(19) United States
(12) Patent Application Publication
(10) Pub. No.: US 2010/0019351 A1
(43) Pub. Date: Jan. 28, 2010

(54) VARACTORS WITH ENHANCED TUNING RANGES

(76) Inventors: Albert Ratnakumar, San Jose, CA (US); Qi Xiang, San Jose, CA (US); Jeffrey Xiaoqi Tung, Milpitas, CA (US)

Correspondence Address: Treyz Law Group, 870 Market Street, Suite 984, San Francisco, CA, 94102, US

(21) Appl. No.: 12/181,309

(22) Filed: Jul. 28, 2008

(51) Int. Cl. H01L 29/93; H01L 21/20

(52) U.S. Cl. 257/595; 438/379; 257/E29.344

(57) ABSTRACT

A varactor may have a first terminal connected to a gate. The gate may be formed from a p-type polysilicon gate conductor. The gate may also have a gate insulator formed from a layer of insulator such as silicon oxide. The gate insulator may be located between the gate conductor and a body region. Source and drain contact regions may be formed in a silicon body region. The body region and the source and drain may be doped with n-type dopant. The varactor may have a second terminal connected to the n-type source and drain. A control voltage may be used to adjust the level of capacitance produced by the varactor between the first and second terminals. A positive control voltage may produce a larger capacitance than a negative control voltage. Application of the negative control voltage may produce a depletion layer in the p+ polysilicon gate layer.

### BACKGROUND

This invention relates to varactors, and more particularly, to varactors with improved tuning ranges for use in integrated circuits.

Modern integrated circuits are often formed from metal-oxide-semiconductor (MOS) transistors. For example, integrated circuits often use complementary metal-oxide-semiconductor (CMOS) transistor technology. CMOS integrated circuits have n-channel metal-oxide-semiconductor (NMOS) and p-channel metal-oxide-semiconductor (PMOS) transistors.

NMOS and PMOS transistors have four terminals—a drain, a source, a gate, and a body. A doped body contact is generally used in forming the body terminal. For example, n-channel transistors have bodies that are doped p-type. In a p-type body, the body contact is formed from a heavily doped p+ region. Source and drain terminals, which are sometimes collectively referred to as source-drain terminals, are formed by doping source and drain regions within the body. In an n-channel transistor, the source and drain regions are heavily doped with n-type dopant (i.e., the source and drain regions are doped n+).

In each transistor, a gate is formed between the source and drain. The gate includes an insulator. The insulator is typically a silicon oxide layer. A gate conductor is formed on top of the gate insulator. The gate conductor may be, for example, a layer of metal. In modern integrated circuits, the gate conductor of an MOS transistor is typically formed from heavily doped polysilicon. A metal silicide layer may be formed on the upper surface of the doped polysilicon gate.

Many integrated circuit applications require capacitors. In certain situations, varactors are required. Varactors, which are sometimes referred to as variable capacitors, exhibit tunable capacitance values. The magnitude of a varactor's capacitance may be controlled by controlling the magnitude of the voltage across the varactor's terminals. Varactors may be used in analog and digital circuits (e.g., to tune a frequency of oscillation or other circuit parameter).

Varactors may be formed from metal-oxide-semiconductor (MOS) structures. An advantage of MOS varactor structures is that structures of this type may be formed using the same process technology that is used to form the metal-oxide-semiconductor transistors on a given metal-oxide-semiconductor integrated circuit.

Varactors may be characterized by figures of merit such as quality factor (Q) and tuning range (Cmax versus Cmin). Satisfactory operation of a varactor requires acceptable tuning range performance without sacrificing quality factor performance. As feature sizes shrink with successive generations of integrated circuit, it can be difficult to achieve varactor performance goals.

In view of these challenges it would be desirable to be able to provide improved metal-oxide-semiconductor varactors.

### SUMMARY

In accordance with the present invention, a varactor may have a first terminal connected to a gate. The gate may be formed from a gate conductor and a gate insulator. The gate conductor may be formed from a doped semiconductor such as doped polysilicon. A p-type dopant may be used in doping the polysilicon. The gate insulator may be formed from a layer of insulator such as silicon oxide. The gate insulator may be located between the gate conductor and a body region. The body of the varactor may be formed from a region of a silicon substrate.

Source and drain contact regions may be formed in the body. The body and the source and drain in the body may be doped with n-type dopant. The varactor may have a second terminal connected to the n-type source and drain.

A control voltage may be used to adjust the level of capacitance produced by the varactor between the first and second terminals. A positive control voltage may produce a larger capacitance than a negative control voltage. When the positive control voltage is applied to the varactor so that the p+ polysilicon gate conductor is at a higher voltage than the n+ source and drain, no depletion layer is formed in the gate, allowing capacitance to be maximized. Application of the negative control voltage may produce a depletion layer in the p+ polysilicon gate layer that helps to reduce the minimum attainable capacitance in the varactor.

Further features of the invention, its nature and various advantages will be more apparent from the accompanying drawings and the following detailed description.

### BRIEF DESCRIPTION OF THE DRAWINGS

FIG. 1 is a cross-sectional side view of a conventional varactor formed from a p-channel metal-oxide-semiconductor structure.

FIG. 2 is a graph showing how capacitance varies as a function of applied voltage in a conventional p-channel metal-oxide-semiconductor varactor of the type shown in FIG. 1.

FIG. 3 is a cross-sectional side view of a conventional varactor formed from an n-channel metal-oxide-semiconductor transistor structure.

FIG. 4 is a cross-sectional side view of a conventional n-type accumulation mode metal-oxide-semiconductor varactor.

FIG. 5 is a cross-sectional side view of a conventional varactor of the type shown in FIG. 4 showing how application of a positive varactor bias voltage leads to polysilicon depletion that reduces the maximum achievable value of capacitance for the varactor.

FIG. 6 is a cross-sectional side view of a conventional varactor of the type shown in FIG. 4 showing how application of a negative varactor bias voltage leads to no polysilicon depletion and thereby maximizes the minimum achievable value of capacitance for the varactor.

FIG. 7 is a cross-sectional side view of an illustrative varactor in accordance with an embodiment of the present invention.

FIG. 8 is a is a cross-sectional side view of an illustrative varactor of the type shown in FIG. 7 showing how application of a positive varactor bias voltage leads to no polysilicon depletion and thereby maximizes the maximum achievable value of capacitance for the varactor in accordance with an embodiment of the present invention.

FIG. 9 is a is a cross-sectional side view of an illustrative varactor of the type shown in FIG. 7 showing how application of a negative varactor bias voltage leads to polysilicon depletion that helps to reduce the minimum achievable value of capacitance for the varactor in accordance with an embodiment of the present invention.

FIG. 10 is a graph comparing a predicted capacitance versus voltage characteristic for a varactor of the type shown in FIG. 8 in accordance with an embodiment of the present invention to the capacitance versus voltage characteristic for a conventional varactor of the type shown in FIG. 4.

FIG. 11 is a graph showing how measured capacitance versus voltage measurements for varactors in accordance with an embodiment of the present invention have been observed to be shifted in voltage relative to the capacitance versus voltage measurements associated with conventional varactors.

FIG. 12 is a cross-sectional side view of a conventional varactor showing how self-aligned implant techniques may be used during fabrication.

FIG. 13 is a cross-sectional side view of a varactor in accordance with an embodiment of the present invention showing how there is a potential for a fully sized photoresist mask to be misaligned with respect to the gate of the varactor structure during an n+ implant.

FIG. 14 is a cross-sectional side view of a varactor in accordance with an embodiment of the present invention showing how there is a potential for a p+photoresist implant mask to be misaligned.

FIG. 15 is a cross-sectional side view of a varactor in accordance with an embodiment of the present invention showing how a p+ implant mask may be configured to help prevent device degradation due to misalignment in accordance with an embodiment of the present invention.

FIG. 16 is a top view showing how the p+ implant region may be configured to underlap the outer perimeter of the polysilicon gate conductor in accordance with an embodiment of the present invention.

FIG. 17 is a flow chart of illustrative steps involved in using a varactor in circuitry on an integrated circuit in accordance with an embodiment of the present invention.

### DETAILED DESCRIPTION

The present invention relates to metal-oxide-semiconductor (MOS) varactors that are formed on integrated circuits. The integrated circuits may be of any suitable type. With one suitable arrangement, metal-oxide-semiconductor varactors in accordance with an embodiment of the invention are formed on integrated circuits such as programmable logic device integrated circuits. This is, however, merely illustrative. Metal-oxide-semiconductor varactors in accordance with embodiments of the invention may be formed on integrated circuits such as digital signal processors, microprocessors, custom integrated circuits, or other integrated circuits. In environments such as these, varactors may be used to provide circuits with controllable capacitance values. Controllable capacitance may be used, for example, to adjust the performance of analog and digital circuits.

Varactors in accordance with the invention have two terminals. In a typical circuit, a direct-current (DC) control voltage may be applied across the varactor terminals to adjust the capacitance provided by the varactor. The adjustable capacitance may be used in an alternating-current (AC) circuit (as an example).

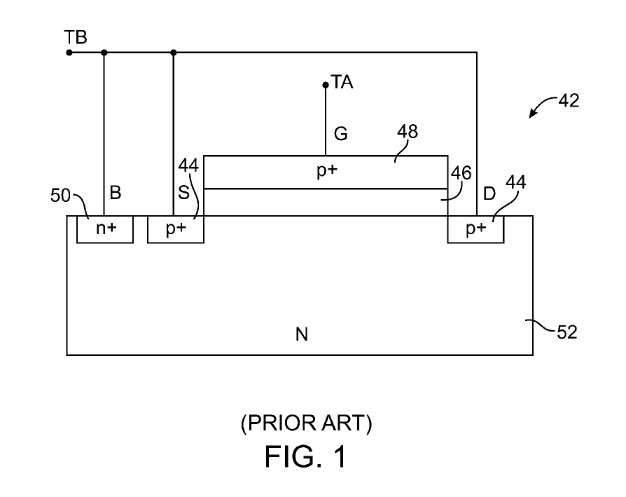

A schematic diagram of a conventional p-channel metal-oxide-semiconductor (PMOS) varactor 42 is shown in FIG. 1. Varactor 42 of FIG. 1 and other the other varactors described herein may share some of the structures that are otherwise associated with MOS transistors on an integrated circuit. For example, varactor 42 has p+ implant regions 44 that are labeled S and D, because these regions resemble the source and drain of a PMOS transistor. Gate conductor 48 may be used to form a gate G. An n+ implant region 50 may be used to form a body contact for n-type body region 52. The body terminal formed by implant region 50 is labeled B in FIG. 1.

Gate G may be formed from gate conductor 48 and a thin layer of insulator 46. Insulator 46 is typically based on silicon dioxide. Gate conductor 48 is generally formed from heavily doped p-type polysilicon.

Conductive paths may be used to connect gate G to a first terminal such as terminal TA and may be used to connect drain D, source S, and body B to a second terminal such as terminal TB. During operation of varactor 42 in a circuit, the voltage across terminals TA and TB serves as a control voltage that adjusts the capacitance exhibited by varactor 42.

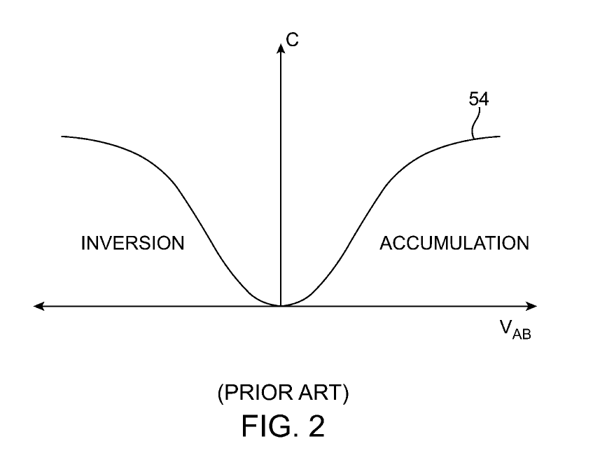

A graph showing a capacitance versus voltage characteristic for a conventional varactor such as varactor 42 is shown in FIG. 2. As shown by FIG. 2, varactor 42 may be operated in accumulation mode or inversion mode.

In inversion mode, the voltage Vab across terminals TA and TB is negative. The negative voltage on terminal TA draws minority carriers (holes) under gate G. In this situation, the holes form a conductive inversion layer in the channel region under gate G.

In accumulation mode, the voltage on terminal TA is positive. The positive voltage on gate G draws electrons under gate G to form a conductive electrode for the varactor (i.e., the lower “plate” in the parallel plate varactor).

At low voltages near Vab values of 0 volts, varactor 42 is said to exhibit depletion. In this situation, a series-connected depletion capacitance Cdep is formed due to the absence of carriers under gate G.

Inversion mode varactors can be subject to large parasitics (e.g., parasitic resistances and parasitic capacitances). Varactors operated in inversion mode can also exhibit overly rapid changes of capacitance with respect to voltage changes, making control operations more sensitive than desired. As a result, accumulation mode operation is generally preferred when using PMOS varactors. Nevertheless, PMOS varactors such as varactor 42 may exhibit undesirable parasitics when operated in accumulation mode. In particular, varactor 42 may exhibit a parasitic body (well) resistance between the region under gate G and body terminal 50.

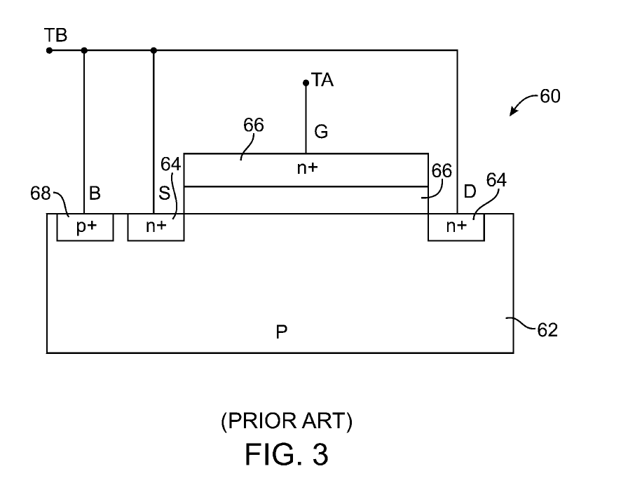

These shortcomings are typically also exhibited by NMOS varactors. A conventional NMOS varactor is shown in FIG. 3. NMOS varactor 60 has a p-type body region 62 and a p+ implant 68 that is used to form an ohmic contact for body B. Source S and drain D may be formed from n+ implant regions 64. Gate G has gate conductor 66 such as silicided n+ polysilicon and silicon dioxide layer 66. Terminal TA may be connected to gate G. Terminal TB may be connected to body B, source S, and drain D.

As with PMOS varactors, parasitics tend to degrade performance when NMOS varactors such as varactor 60 of FIG. 3 are operated in inversion mode. Inversion mode NMOS varactors also tend to be overly sensitive by exhibiting excessively large changes in capacitance for a given amount of voltage change. Accumulation mode NMOS varactors have more acceptable sensitivity characteristics than inversion mode NMOS varactors. However, accumulation mode NMOS varactors also still suffer from non-negligible parasitic well resistances that degrade performance.

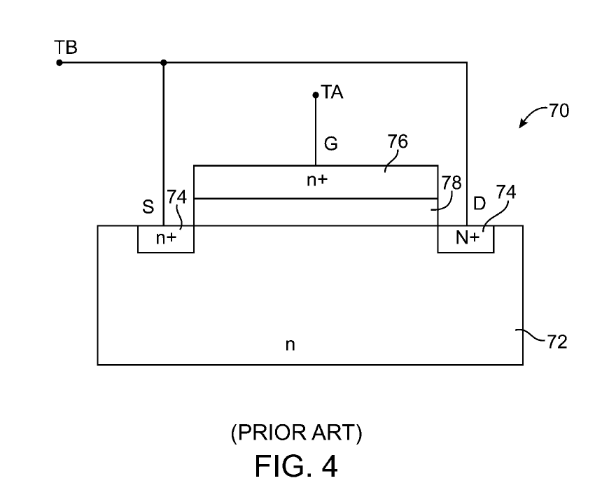

Because of the shortcomings of inversion mode varactors and the poor performance of NMOS and PMOS varactors in accumulation mode, modern varactors are typically formed using an n-type accumulation mode structure of the type shown in FIG. 4. As shown in FIG. 4, n-type accumulation mode varactor 70 has an n-type body region 72. Source S and drain D are formed from n+ implant regions 74. Terminal TB is connected to the source S and drain D via conductive paths. Terminal TA is connected to the gate G. The gate G is formed from a silicided n+ polysilicon gate conductor layer 76 on top of a silicon dioxide layer 78.

Varactor structures of the type shown in FIG. 4 exhibit superior performance to the PMOS and NMOS varactors of FIGS. 1 and 2. In particular, there is no significant parasitic well resistance in n-type accumulation mode varactors because the accumulated layers of electrons under gate G can make direct ohmic contact with the n+ source and drain regions. Varactors of this type also benefit from the use of high mobility carriers (electrons). Moreover, because operation is in accumulation mode, excessive sensitivity in the form of undesirably large changes in capacitance for a given voltage change can be avoided.

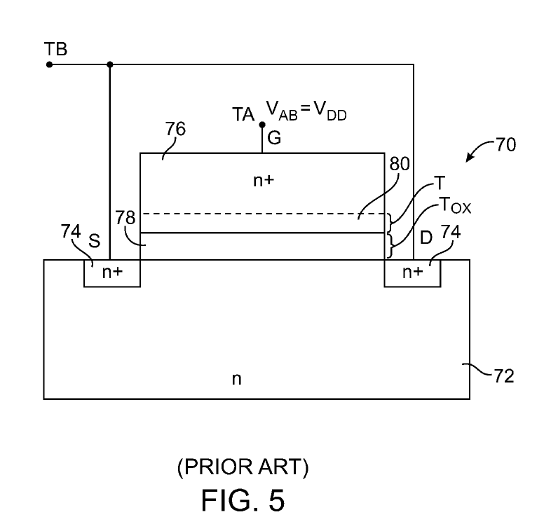

Despite these advantages, n-type accumulation mode varactors suffer from degraded capacitance tuning ranges due to formation of a depletion layer in the polysilicon gate. The capacitance produced by an n-type accumulation mode structure varies from a minimum capacitance Cmin when negative control voltages are applied to a maximum capacitance Cmax when positive control voltages are applied. As shown in FIG. 5, when a positive voltage Vdd is applied across varactor 70 to place varactor 70 in its maximum capacitance state, a depletion layer 80 of thickness T forms in n+ polysilicon gate layer 76 at the interface with silicon oxide layer 78. The depletion layer results from the attraction of negative free carriers (i.e., the majority carrier electrons in the n+ polysilicon) towards the applied positive voltage on terminal TA and away from gate oxide 78. In effect, the depletion layer serves to extend the thickness of oxide layer 78 (Tox) to a larger value (Tox+T). The capacitance of varactor 70 scales with the inverse of the thickness of the insulating layer between TA and TB, so the presence of depletion layer 80 reduces the magnitude of the maximum attainable capacitance for varactor 70. Particularly in modern devices in which Tox is small, the contribution of T to the capacitance of varactor 70 is generally not negligible.

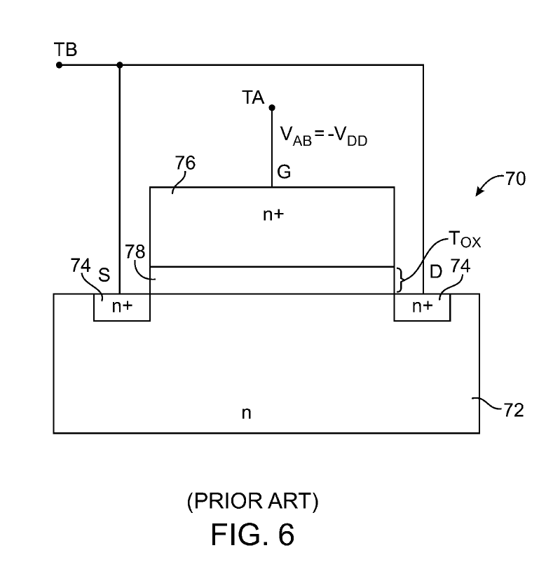

FIG. 6 shows how no depletion layer is present in n+ polysilicon gate conductor 76 when varactor 70 is biased with a negative voltage of −Vdd to place varactor 70 in its minimum capacitance state. The absence of the depletion layer in this state ensures that the minimum capacitance of varactor 70 will exhibit its maximum possible value.

As a result of this behavior, depletion layer effects in conventional n-type accumulation mode varactors are counterproductive. When attempting to bias varactor 70 with a positive voltage to maximize the capacitance of varactor 70, the presence of the depletion layer degrades the maximum attainable capacitance. When attempting to bias varactor 70 with a negative voltage to minimize the capacitance of varactor 70, there is no depletion layer, so the minimum capacitance is fixed at the value associated with oxide thickness Tox.

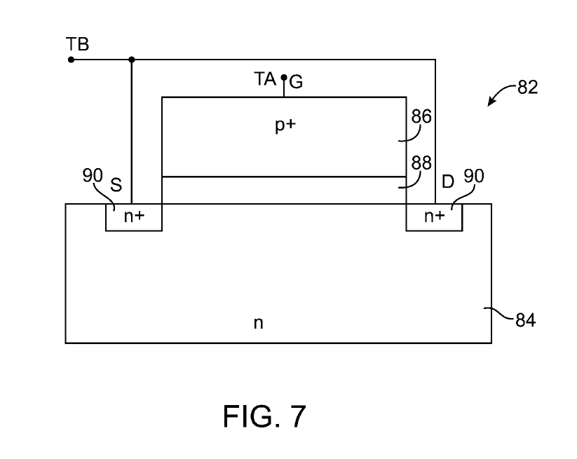

A varactor 82 in accordance with an embodiment of the present invention is shown in FIG. 7. As shown in FIG. 7, varactor 82 may have an n-type body (well) 84. When operated in accumulation mode, electrons, which exhibit higher mobility than holes, are used in forming a lower capacitor electrode for varactor 82. Highly doped regions such as n+ implant regions 90 serve as contact regions and may be used in forming source S and drain D. Regions 90 are formed immediately adjacent to gate G, so that the source S abuts one end of the highly conductive region under gate G and so that drain D abuts the other end of this region under gate G. There is no need for other contacts in body region 84, although such contacts may be provided if desired. Well 84 and regions 90 may be formed from a semiconductor substrate such as a silicon substrate. In this type of arrangement, the n+ regions are formed from silicon into which a relatively large amount of n-type dopant has been incorporated (e.g., by ion implantation).

Varactor terminal TB may be connected to source S and drain D using conductive paths. Terminal TA may be connected to the gate portion of varactor 82 using a conductive path. The gate of varactor 82 includes a conductive gate layer 86 and a gate insulating layer 88. Conductive layer 86 may be formed from a p+ semiconductor such as polysilicon doped p+ using p-type dopant. The p+ doped polysilicon layer may, if desired, include a silicided upper portion (e.g., a layer of metal silicide). The presence of the silicide layer may help to reduce the resistance of the gate material. Gate insulating layer 88 may be formed from silicon oxide or any other suitable insulator (e.g., insulators including hafnium or other materials). The conductive paths that connect regions 90 to terminal TB and that connect conductive layer 86 to terminal TA may be formed from metal or other suitable conductors.

A control voltage Vab (i.e., a DC voltage) may be applied to varactor 82 across terminals TA and TB. A minimum capacitance Cmin may be produced when a negative control voltage is applied (e.g., −0.5 volts) and a maximum capacitance Cmax may be produced when a positive control voltage is applied (e.g., 2.0 volts).

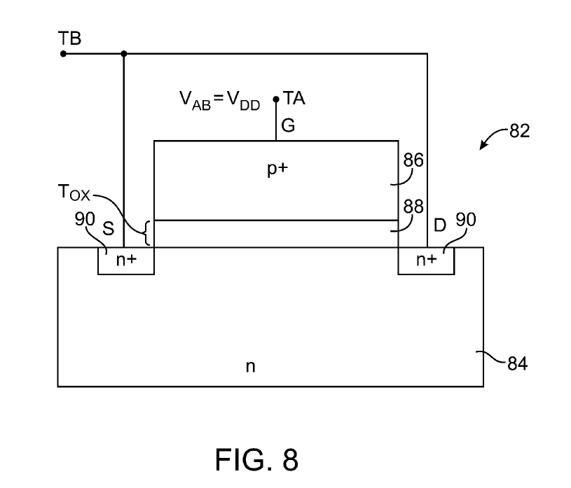

When a positive voltage is applied, holes are repelled from terminal TA and accumulate at the interface between polysilicon 86 and oxide 88. As a result, no depletion layer is formed in polysilicon layer 86. The thickness of the insulating layers in varactor 82 is therefore equal to the thickness Tox of oxide layer 88, as shown in FIG. 8.

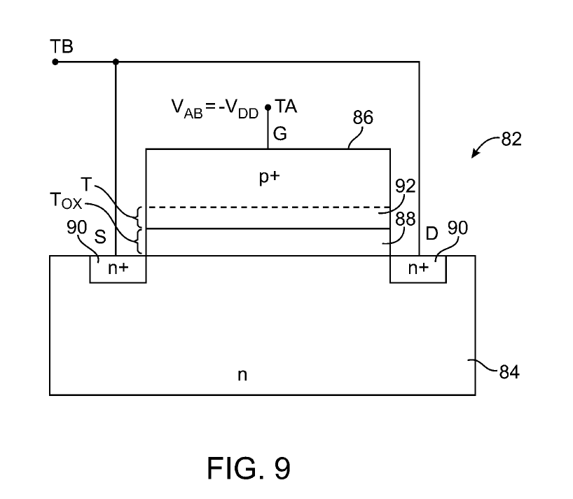

When a negative voltage is applied across varactor 82, the negative voltage produces a depletion region such as depletion region 92 of FIG. 9. The depletion region 92 is formed because the negative voltage on terminal TA tends to attract majority carriers (holes) towards terminal TA, away from the interface between p+ polysilicon layer 86 and oxide layer 88. In this situation, the thickness of the region between body 84 and the conductive portions of layer 86 is equal to the thickness Tox of oxide layer 88 plus the thickness T of depletion layer 92.

In contrast to the conventional n-type accumulation mode varactor structure of FIG. 4, depletion layer effects in varactors such as varactor 82 of FIG. 7 are productive, rather than being counterproductive. When biasing varactor 82 with a positive voltage to maximize the capacitance of varactor 82, the absence of the depletion layer helps by not undesirably lowering the capacitance as with the FIG. 4 structure. When biasing varactor 82 with a negative voltage to minimize the capacitance of varactor 82, the presence of depletion layer 92 increases the thickness of the insulating region between the two electrodes in the varactor and helps to lower the capacitance. The depletion layer therefore helps in minimizing the varactor capacitance and does not have an adverse impact when the varactor capacitance is being maximized.

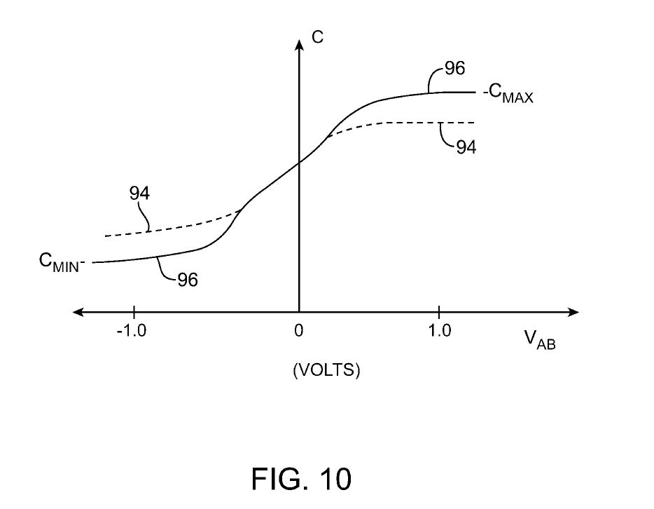

A graph showing the expected behavior of varactor 82 in comparison to a conventional varactor such as varactor 70 of FIG. 4 is shown in FIG. 10. In the graph of FIG. 10, dashed line 94 represents the capacitance versus voltage characteristic of varactor 70, whereas solid line 96 represents the capacitance versus voltage characteristic of varactor 82. As shown in the graph, the maximum capacitance value Cmax of varactor 82 is larger than the maximum capacitance of varactor 70 and the minimum capacitance Cmin of varactor 82 is smaller than the minimum capacitance of varactor 70. As a result, varactor 82 has a larger tuning range (Cmax versus Cmin) than conventional varactor 70.

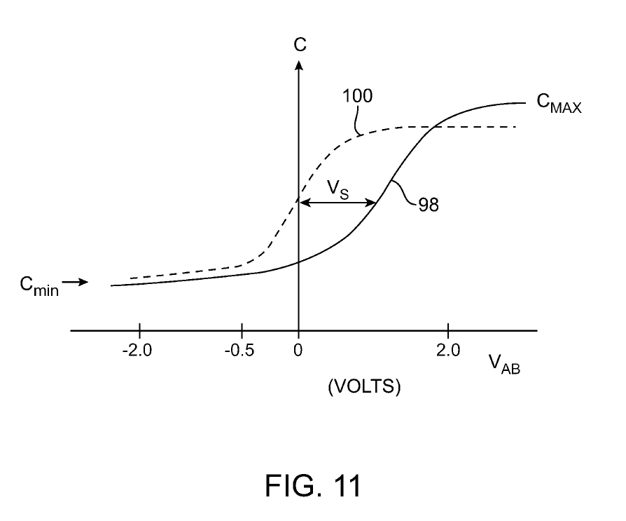

FIG. 11 shows measured data (solid line 98) for varactor 82. As shown by comparison to dashed line 100, which represents a nominal or expected C-V characteristic for varactor 82 in the absence of built-in-fields, the measured data for varactor 82 is shifted toward higher values of applied voltage Vab. The position of solid line 98 relates to the work function of polysilicon 86. The p+ polysilicon of layer 86 in proximity to the n-well creates a built-in electric field due to the work function difference between the p+ polysilicon and the n-well (body region 84). In order to accumulate electrons in the channel region under gate G, an extra positive bias (voltage shift Vs) must be applied to overcome the field. This is shown in the shift of measured results line 98 relative to unshifted line 98.

The measured value of Vs is about 1.0-1.1 volts for p+ doping concentrations of about 10²¹ cm⁻³. The tuning range (variation between Cmax and Cmin) for varactor 82 has been measured to improve by 10% relative to the tuning range for conventional varactor 70. Moreover, as a result of the voltage shift and potentially other factors such as reductions in tunneling current through gate oxide, measured leakage currents have been reduced by over 100×. These reductions in leakage current have improved the quality factor Q of the varactor.

In general, there is a tradeoff between quality factor Q and tuning range. To achieve high Q values, it might be desirable to use short channel lengths (gate lengths), as these short gate lengths demonstrate low levels of parasitic well resistance. Structures formed with short gate lengths tend to exhibit reduced tuning ranges, however, because of the presence of non-negligible parasitic capacitances Cgs due to fringing electromagnetic fields. When Cgs is non-negligible, the tuning range (Cmax+Cgs)/(Cmin+Cgs) tends to be reduced.

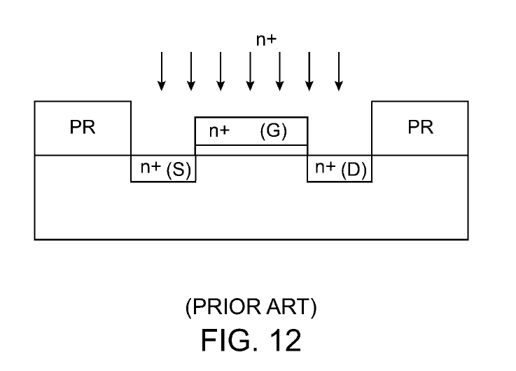

In a given semiconductor fabrication process, design rules dictate the minimum acceptable gate length LGmin. In conventional varactors, gate lengths LG of about 2×-3× LGmin are used to avoid poor tuning ranges. In arrangements such as these, in which the lateral sizes of the gates are not particularly small, the lack of a self-aligned gate fabrication process is not anticipated to pose significant fabrication challenges. If desired, gate mask arrangements may be used that provide additional design margin for varactor 82. The desirability of these gate arrangements may be understood with reference to FIGS. 12, 13, and 14.

During fabrication of conventional varactor 70, a self-aligned n+ implant process may be used. As shown in FIG. 12, a patterned photoresist layer PR may be used to define an opening for an n+ implant. The gate G in a conventional varactor 70 requires an n+ implant. It is therefore possible to implant gate G while simultaneously implanting source S and drain D. In this situation, the polysilicon of gate G forms a self-aligned implant mask for the source S and drain D.

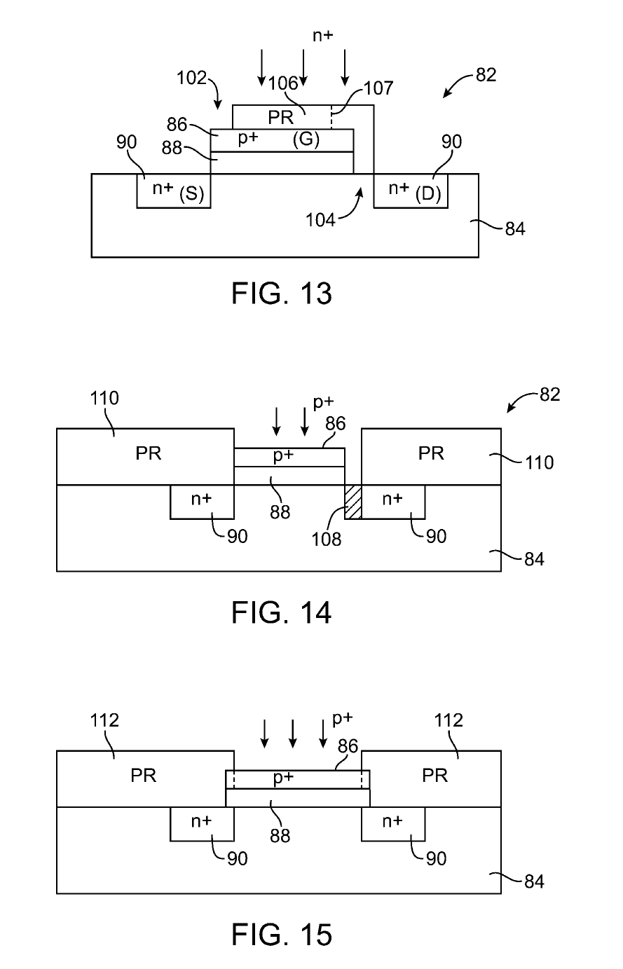

When forming varactors such as varactor 82 of FIG. 7, p+ region 86 may be covered with a patterned photoresist layer PR during n+ implant steps. As shown in FIG. 13, there may be misalignment between n+ implant mask PR and gate G. This may lead to an unintended n+ implant in region 102 and an unintended unimplanted region 104. The electrical properties of region 102 are not expected to significantly affect the behavior of varactor 82. The unintended unimplanted region 104 may contribute an undesired parasitic resistance that tends to reduce the quality factor Q, and can be avoided by using a smaller mask 106. With a smaller mask, the right-hand edge of the mask will be aligned with dashed line 107 and the left-hand edge will be similarly positioned, thereby avoiding unintended unimplanted regions such as region 104.

During the p+ ion implantation step that is used in forming p+ layer, photoresist mask layer 110 may be misaligned as shown in FIG. 14, leading to an unintended p+ implant region 108. This can create a high resistance path in body region 84 due to the formation of back-to-back diodes and can be avoided by using a p+ implant mask such as such as mask 112 of FIG. 15, which has an opening that is smaller than gate conductive layer 86.

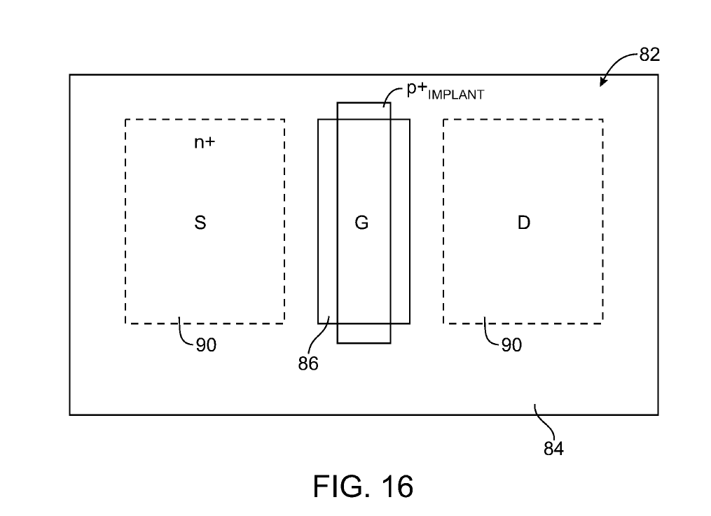

A top view of varactor 82 showing how the p+ implant region may be configured to underlap the outer perimeter of polysilicon gate conductor 86 in this way is presented in FIG. 16.

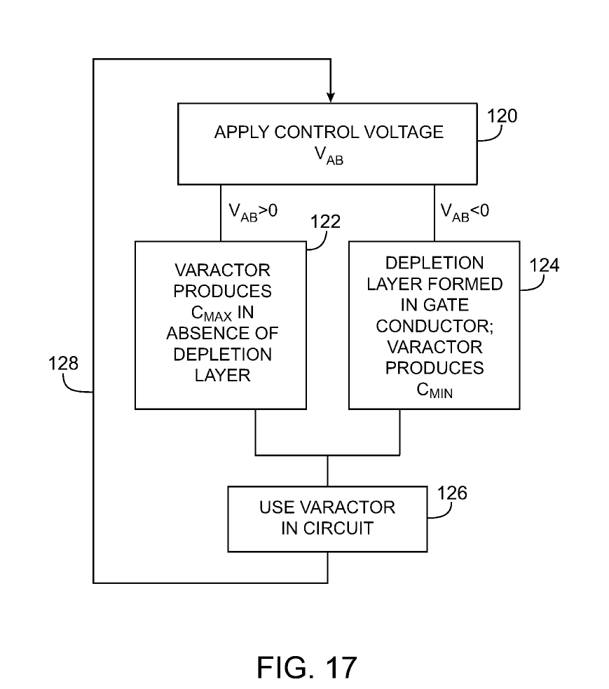

A flow chart of illustrative steps involved in using varactor 82 in circuitry on an integrated circuit is shown in FIG. 17.

At step 120, circuitry in an integrated circuit may be used to apply a control voltage Vab (DC) to varactor 82 across terminals TA and TB. If the control voltage is positive (e.g., Vab=2.0 volts as an example), a maximum capacitance value Cmax may be produced without creating a depletion layer in gate conductor 86 (step 122). If the control voltage is negative (e.g., Vab=−0.5 volts as an example), a depletion layer in polysilicon layer 86 and a corresponding minimum capacitance value Cmin may be produced (step 124) by varactor 82. As shown schematically by step 126, the capacitance that is produced across terminals TA and TB may be used in a circuit (e.g., to tune a circuit, etc.). As indicated by line 128, the varactor adjustment and usage operations of FIG. 17 may be performed continuously during operation of an integrated circuit.

If desired, varactors of the type shown in FIG. 7 may be provided in which the p-type regions are replaced by n-type regions and in which the n-type regions are replaced by p-type regions. While performance may be satisfactory in this type of device for some applications, the generally larger resistances that are associated with p-type bodies when operated in accumulation (due to the lower mobility of holes than electrons) may lead to undesirably larger parasitic well resistances.

The foregoing is merely illustrative of the principles of this invention and various modifications can be made by those skilled in the art without departing from the scope and spirit of the invention.

What is claimed is:

1. A varactor, comprising:
a semiconductor body;
a gate having a p+ gate conductor; and
at least one n+ contact region in the body adjacent to the p+ gate conductor.

2. The varactor defined in claim 1 further comprising a gate insulator between the p+ gate conductor and the body.

3. The varactor defined in claim 2 wherein the gate insulator comprises silicon oxide.

4. The varactor defined in claim 1 wherein the body comprises a portion of a silicon wafer.

5. The varactor defined in claim 1 wherein the p+ gate conductor comprises a layer of polysilicon.

6. The varactor defined in claim 1 wherein the at least one n+ contact region comprises an n+ ion-implantation region.

7. The varactor defined in claim 1 wherein the at least one n+ contact region comprises a source n+ region and a drain n+ region on opposing sides of the p+ gate conductor.

8. The varactor defined in claim 1 wherein the at least one n+ contact region comprises source and drain n+ regions located adjacent to opposite ends of the p+ gate conductor and wherein the p+ gate conductor comprises p+ polysilicon.

9. The varactor defined in claim 8 further comprising a first terminal connected to the source and drain n+ regions.

10. The varactor defined in claim 9 further comprising a second terminal connected to the gate conductor.

11. The varactor defined in claim 1 further comprising a first terminal connected to the n+ contact region.

12. The varactor defined in claim 11 further comprising a second terminal connected to the gate conductor.

13. The varactor defined in claim 12 wherein the gate conductor comprises a p+ polysilicon layer.

14. A method of producing a capacitance in a varactor having a p+ gate conductor and n+ source and drain conductors, comprising:
producing a first capacitance value between the p+ gate conductor and the n+ source and drain conductors without creating a depletion layer in the p+ gate conductor by biasing the p+ gate conductor with a positive voltage with respect to the n+ source and drain conductors; and
producing a second capacitance value between the p+ gate conductor and the n+ source and drain conductors that is smaller than the first capacitance value by creating a depletion layer in the p+ gate conductor by biasing the p+ gate conductor with a negative voltage with respect to the n+ source and drain conductors.

15. The method defined in claim 14 wherein the p+ gate conductor comprises a p+ polysilicon layer, the method further comprising creating the depletion layer in the p+ polysilicon layer.

16. The method defined in claim 14 wherein the p+ gate conductor comprises a p+ polysilicon layer and wherein a gate oxide is located between the p+ polysilicon layer and a silicon body region in which the n+ source and drain conductors are located, the method further comprising creating the depletion layer in the p+ polysilicon layer at an interface between the gate oxide and the p+ polysilicon layer.

17. A varactor having first and second terminals, comprising:
a silicon body;
n+ source and drain regions in the body that are connected to the second terminal; and
a p+ gate located between the n+ source region and the n+ drain region that is connected to the first terminal, wherein the varactor produces an adjustable capacitance between the first and second terminals based on an applied voltage between the first and second terminals.

18. The varactor defined in claim 17 wherein the p+ gate comprises a p+ gate conductor on a gate insulating layer.

19. The varactor defined in claim 18 wherein the p+ gate conductor comprises p+ polysilicon.

20. The varactor defined in claim 19 wherein the gate insulating layer comprises an insulator located between the p+ polysilicon and the body.
